(19) United States
(12) Patent Application Publication
(10) Pub. No.: US 2024/0355925 A1
(43) Pub. Date: Oct. 24, 2024

(54) GATE-SOURCE STRUCTURE AND MANUFACTURING METHOD THEREOF, AND ASYMMETRIC TRENCH MOSFET AND MANUFACTURING METHOD THEREOF

(71) Applicant: Hangzhou Silicon-Magic Semiconductor Technology Co., Ltd, Hangzhou City (CN)

(72) Inventors: Yanggang Ou, Hangzhou City (CN); Jiamin Luo, Hangzhou City (CN)

(73) Assignee: Hangzhou Silicon-Magic Semiconductor Technology Co., Ltd, Hangzhou City (CN)

(21) Appl. No.: 18/390,943

(22) Filed: Dec. 20, 2023

(30) Foreign Application Priority Data
Apr. 18, 2023 (CN) 202310428937.8

(51) Int. Cl. H01L 29/78; H01L 29/423; H01L 29/66

(52) U.S. Cl. CPC H01L 29/7835; H01L 29/4236; H01L 29/6659

(57) ABSTRACT

A gate-source structure of an asymmetric trench MOSFET, includes: a substrate of a first doping type; an epitaxial layer of the first doping type on the substrate; a current spreading layer of the first doping type in the epitaxial layer; a trench extending from a surface to an inside of the current spreading layer; a source conductor located in the trench; a first dielectric layer, located between the source conductor and an inner surface of the trench, isolating from the source conductor and the inner surface of the trench; a gate conductor located in the trench; an isolation dielectric layer, located between the source conductor and the gate conductor, isolating from the source conductor and the gate conductor; and a gate dielectric layer, located between the gate conductor and the inner surface of the trench, isolating from the gate conductor and the inner surface of the trench.

This application relates to the technical field of semiconductors, and in particular, to a gate source-structure and a manufacturing method thereof, and an asymmetric trench MOSFET and a manufacturing method therefor.

### BACKGROUND

Traditional planar silicon carbide (SIC) MOSFET (Metal Oxide Semiconductor Field Effect Transistor) usually has a large on-resistance due to the JFET effect. Trench MOSFET (Metal Oxide Semiconductor Field Effect Transistor) has the advantages of high input impedance, small driving current, fast switching speed, and good high temperature characteristics, and is widely used in the field of power electronics.

However, for general trench MOSFETs (Metal Oxide Semiconductor Field Effect Transistor), the reliability of the gate dielectric layer has become the significant factor that restricts the reliability of trench MOSFET devices.

### SUMMARY

According to one or more embodiments of the present disclosure, a gate-source structure of an asymmetric trench MOSFET, includes: a substrate of a first doping type; an epitaxial layer of the first doping type on the substrate; a current spreading layer of the first doping type in the epitaxial layer; a trench extending from a surface to an inside of the current spreading layer; a source conductor located in the trench; a first dielectric layer, located between the source conductor and an inner surface of the trench, isolating from the source conductor and the inner surface of the trench; a gate conductor located in the trench; an isolation dielectric layer, located between the source conductor and the gate conductor, isolating from the source conductor and the gate conductor; a gate dielectric layer, located between the gate conductor and the inner surface of the trench, isolating from the gate conductor from the inner surface of the trench; wherein: the source conductor includes: a first portion opposite to a side of the gate conductor and a second portion opposite to a bottom of the gate conductor; and the first portion and the second portion are perpendicular and connected to each other.

According to one or more embodiments of the present disclosure, an asymmetric trench MOSFET, includes: a substrate of a first doping type; an epitaxial layer of the first doping type on the substrate; a current spreading layer of the first doping type in the epitaxial layer; a trench extending from a surface to an inside of the current spreading layer; a source conductor located in the trench; a first dielectric layer, located between the source conductor and an inner surface of the trench, isolating from the source conductor and the inner surface of the trench; a gate conductor located in the trench; an isolation dielectric layer, located between the source conductor and the gate conductor, isolating from the source conductor and the gate conductor; a gate dielectric layer, located between the gate conductor and the inner surface of the trench, isolating from the gate conductor and the inner surface of the trench; a first body region located adjacent a first sidewall of the trench; a second body region located adjacent a second sidewall of the trench, the first sidewall of the trench opposite to the second sidewall of the trench; wherein: the source conductor includes: a first portion opposite to a side of the gate conductor and a second portion opposite to a bottom of the gate conductor; and the first portion and the second portion are perpendicular and connected to each other.

According to one or more embodiments of the present disclosure, a method for manufacturing a gate-source structure of an asymmetric trench MOSFET, including: sequentially forming an epitaxial layer and a current spreading layer on a substrate, the substrate, the epitaxial layer and the current spreading layer being of a first doping type; forming a trench extending from a surface to an inside of the current spreading layer; forming a source conductor in the trench, and a first dielectric layer between the source conductor and an inner surface of the trench, the first dielectric layer isolating from the source conductor and the trench the inner surface; and forming a gate conductor, an isolation dielectric layer between the source conductor and the gate conductor and a gate dielectric layer between the gate conductor and the inner surface of the trench in the trench, the isolation dielectric layer isolating from the source conductor and the gate conductor and the gate dielectric layer isolating from the gate conductor and the inner surface of the trench.

According to one or more embodiments of the present disclosure, a method of manufacturing an asymmetric trench MOSFET, includes: sequentially forming an epitaxial layer and a current spreading layer on a substrate, the substrate, the epitaxial layer and the current spreading layer being of a first doping type; forming a trench extending from a surface to an inside of the current spreading layer; forming a source conductor in the trench, and a first dielectric layer between the source conductor and an inner surface of the trench, the first dielectric layer isolating from the source conductor and an inner surface of the trench; forming a gate conductor, an isolation dielectric layer between the source conductor and the gate conductor and a gate dielectric layer between the gate conductor and the inner surface of the trench in the trench; the isolation dielectric layer isolating from the source conductor and the gate conductor and the gate dielectric layer isolating from the gate conductor and the inner surface of the trench; and forming a first body region and a second body region of a second doping type; wherein: the first body region located adjacent to a first sidewall of the trench; and the second body region located adjacent to a second sidewall of the trench, the first sidewall of the trench being opposite to the second sidewall of the trench.

### BRIEF DESCRIPTION OF THE DRAWINGS

FIG. 1 show a schematic diagram of cross-sectional view of an asymmetric trench MOSFET according to one or more embodiments of the present disclosure.

FIG. 2A-2I show sectional views of stages of a manufacturing method of the asymmetric trench MOSFET device according to one or more embodiments of the present disclosure.

FIG. 3A-3D show sectional views of stages of a manufacturing method of the asymmetric trench MOSFET device according to one or more embodiments of the present disclosure.

### DETAILED DESCRIPTION

The present disclosure will be described in more detail below with reference to the accompanying drawings. In each accompanying drawing, the same elements are denoted by the similar reference numerals. For the sake of clarity, each part in the accompanying drawings is not drawn to scale. In addition, some well-known parts may not be shown. For the sake of simplicity, a semiconductor structure obtained after several steps may be described in a drawing.

It should be understood that, during the description of the structure of a device, when a layer or region is referred to as being located “on” or “above” another layer or region, it may be directly located on another layer or region, or other layers or regions are also included between it and another layer or region. Moreover, if the device is turned over, the layer or region will be located “under” or “below” another layer or region.

In order to describe the situation of being directly located on another layer or region, the expression “directly on . . . ” or “on and adjacent to . . . ” will be adopted herein.

Unless otherwise specified below, various parts of the semiconductor device may be composed of materials known to those skilled in the art. Semiconductor materials include, for example, III-V semiconductors, such as gallium arsenide (GaAs), gallium nitride (GaN), etc., IV-IV semiconductors, such as silicon carbide (SiC), etc., II-VI compound semiconductors, such as cadmium sulfide (CdS), cadmium telluride (CdTe), etc., and Group IV semiconductors, such as silicon (Si), germanium (Ge), etc. The gate conductor can be formed of various materials capable of conducting electricity, such as a metal layer, a doped polysilicon layer, or a stacked gate conductor including a metal layer and a doped polysilicon layer, or other conductive materials, such as TaC, TiN, TaSiN, HfSiN, TiSiN, TiCN, TaAlC, TiAlN, TaN, PtSix, Ni₃Si, Pt, Ru, W, and combinations of various conductive materials. The gate dielectric may be made of SiO2 or a material with a dielectric constant greater than SiO₂, including oxides, nitrides, oxynitrides, silicates, aluminates, and titanates, for example. Also, the gate dielectric may not only be formed of materials known to those skilled in the art, but also materials for gate dielectrics developed in the future may be used.

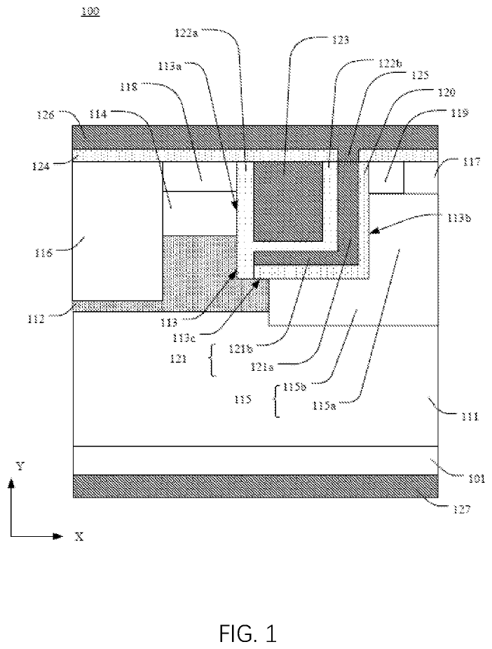

FIG. 1 is a cross-sectional view of an asymmetric trench MOSFET according to one or more embodiments of the present disclosure. In the present disclosure, the first doping type is one of N-type and P-type, and the second doping type is the other one of N-type and P-type. Doping N-type dopants, such as P and As, into the semiconductor layer can form the N-type semiconductor layer. Doping a P-type dopant, such as B, into the semiconductor layer can form a P-type semiconductor layer.

As shown in FIG. 1, the asymmetric trench MOSFET 100 includes a substrate 101, an epitaxial layer 111 located on the first surface of the substrate 101, and a current spreading layer (CSL layer) 112 located on the epitaxial layer 111. The substrate 101 is used as a drain region of the device and has a first doping type. In one or more embodiments, the substrate 101 is heavily doped with N type. The epitaxial layer 111 serves as a drift region of the device and has the first doping type. In one or more embodiments, the epitaxial layer 111 is lightly doped with N type. The current spreading region 112 is of the first doping type, and in one or more embodiments, is N-type heavily doped to further reduce the on-resistance.

The asymmetric trench MOSFET 100 includes a trench 113, a source conductor 121 and a gate conductor 123 located in the trench 113. The trench 113 extends from the upper surface of the current spreading layer 112 to the inside thereof, and the bottom of the trench 113 does not exceed the bottom of the current spreading layer 112, that is, the trench 113 is located in the current spreading layer 112. The trench 113 includes a first sidewalls 113a (i.e., the left side wall in FIG. 1), a second sidewalls 113b (i.e., the right side wall in the FIG. 1) and a bottom wall 113c. The first sidewall 113a is opposite to the second sidewall 113b, and the bottom wall 113c is connected to the first sidewalls 113a and the second sidewalls 113b. The first sidewalls 113a, the second sidewalls 113b and the bottom wall 113c are formed to the inner surface of the trench 113.

The source conductor 121 includes a first portion 121a and a second portion 121b which are perpendicular and connected to each other to form a L-shaped source conductor 121. The source conductor 121 is isolated from the inner surface of the trench 113 by the first dielectric layer 120; specifically, the first portion 121a of the source conductor 121 is isolated from the second sidewalls 113b of the trench 113 by the first dielectric layer 120, and the second portion 121b is isolated from the bottom wall 113c of the trench 113 by the first dielectric layer 120.

The gate conductor 123 is located above the second portion 121b of the source conductor 121, and near the first side of the first portion 121a of the source conductor 121 (i.e., the left side of the first portion 121a in FIG. 1). The first portion 121a of the source conductor 121 is opposite to a side of the gate conductor 123, and the second portion 121b is opposite to the bottom of the gate conductor 123. The L-shaped structure of the source conductor 121 makes the source conductor 121 and the gate conductor 123 have a larger relative area which further increases the gate-source capacitance.

The first side of the gate conductor 123 (i.e. the left side in FIG. 1) is isolated from the inner surface of the trench 113 by the gate dielectric layer 122a, and the bottom and the second side of the gate conductor 123 are isolated from the source conductor 121 by the isolation dielectric layer 122b. Specifically, the first side of the gate conductor 123 is isolated from the first sidewall 113a of the trench 113 by the gate dielectric layer 122a, the bottom of the gate conductor 123 is isolated from the second portion 121b of the source conductor 121 by the isolation dielectric layer 122b, and the second side of the gate conductor 123 is isolated from the first portion of the source conductor 121 by the isolation dielectric layer 122b. In one or more embodiments, the thickness of the isolation dielectric layer 122b is greater than 100 nm.

The asymmetric trench MOSFET 100 includes a first body region 114, a second body region 115, a first doped region 116, a second doped region 117, a third doped region 118, and a fourth doped region 119. The first body region 114, the second body region 115, the first doped region 116, and the second doped region 117 are of the second doping type, and the third doped region 118 and the fourth doped region 119 are of the first doping type.

The first body region 114 is located in the current spreading layer 112, the third doped region 118 is located in the first body region 114. The first body region 114 and the third doped region 118 are adjacent to the first sidewall 113a of the trench 113. The first doped region 116 is adjacent a side of the first body region 114 away from the trench 113. Specifically, the first doped region 116 extends from the upper surface to the inside of the current spreading layer 112, and the extension depth of the first doped region 116 in the current spreading layer 112 is greater than the extension depth of the trench 113 in the current spreading layer 112. That is, the depth of the first doped region 116 is greater than the depth of the trench 113 so as to further reduce the electric field intensity of the gate dielectric layer 122a to protect the gate dielectric layer 122a. In one or more embodiments, the depth of the first doped region 116 is greater than 0.1 um˜0.5 um.

In one or more embodiments, the bottom of the first doped region 116 does not exceed the bottom of the current spreading layer 112, that is, the first doped region 116 is located in the current spreading layer 112. In one or more embodiments, the bottom of the first doped region 116 may also extend the bottom of the current spreading layer 112 into the epitaxial layer 111. The skill in the art can set the depth of the first doped region 116 as required, which is not limited therein.

The second body region 115 includes a third portion 115a located adjacent to the second sidewall 113b of the trench 113, and a fourth portion 115b located below the trench 113. The third portion 115a and the fourth portion 115b are connected to form an integration. The second body region 115 surrounds the second sidewall 113b of the trench 113, at least a part of the bottom wall 113c of the trench 113, and a corner formed by the second sidewall 113b of the trench 113 and the bottom wall 113c of the trench 113. Wherein, one end of the fourth portion 115b is connected to the end of the third portion 115a, and the other end of the fourth portion 115b extends toward the direction away from the third part 115a.

The second portion 121b of the source conductor 121 and the fourth portion 115b of the second body region 115 extend toward the first direction (i.e., the direction of the negative X axis in FIG. 1), and in the first direction, the end of the fourth portion 115b away from the third portion 115a does not exceed the end of the second portion 121b away from the first portion 121a.

In one or more embodiments, the bottom of the second body region 115 exceeds the bottom of the current spreading layer 112 and extends to the inside of the epitaxial layer 111. In one or more embodiments, the bottom of the second body region 115 does not exceed the bottom of the current spreading layer 112, and the second body region 115 is located in the current spreading layer 112.

The second doped region 117 and the fourth doped region 119 are located in the second body region 115, specifically, located in the third portion 115a of the second body region 115. The fourth doped region 119 is adjacent to the second sidewall 113b of the trench 113, and the second doped region 117 is adjacent to the side of the fourth doped region 119 away from the trench 113.

The asymmetric trench MOSFET 100 includes an interlayer dielectric layer 124, and the interlayer dielectric layer 124 covers the surface of the first doped region 116, the surface of the second doped region 117, the surface of the third doped region 118, the surface of the fourth doped region 119, the surface of the gate conductor 123, and a part of the surface of the source conductor 121. A conductive channel 125 is located in the interlayer dielectric layer 124, and the conductive channel 125 penetrates the interlayer dielectric layer 124 to the source conductor 121.

The asymmetric trench MOSFET 100 further includes a source electrode 126 and a drain electrode 127. The source electrode 126 is located on the surface of the interlayer dielectric layer 124 and is in contact with the surface of the source conductor 121 via the conductive channel 125. The drain electrode 127 is located on the second surface of the substrate 101 and is in contact with the substrate 101. The first surface and the second surface of the substrate 101 are opposite to each other.

In one or more embodiments, when forward bias voltage is applied to the gate conductor 123, an inversion channel forms in the first body region 114 to turn on the device. When zero or negative bias voltage is applied to the gate conductor 123, the device turns off. When the device applied reverse bias, the depletion regions are formed between the first doped region 116 and the epitaxial layer 111 (drift region), and formed between the second body region 115 and the epitaxial layer 111 (drift region).

When the source electrode 126 of the device is applied with a forward voltage and the drain electrode 127 is grounded (the third quadrant working area), the inversion channel forms in the second body region 115 adjacent to the first dielectric layer 120 in which electron flow to drain region via the channel. By controlling the thickness of the first dielectric layer 120 and the doping concentration of area of the second body region 115 near the first dielectric layer 120, the forward conduction voltage of the channel diode is lower than the conduction voltage of the device body diode. When a forward voltage is applied to the source electrode 126 of the device and the drain electrode 127 is grounded (the third quadrant operating range), the conduction of channel diode is earlier than the body diode. By controlling the thickness of the first dielectric layer 120 and the doping concentration of the second body region 115 near the surface of the first dielectric layer 120, a turn-on voltage of about 1V˜3V for the trench diode can be realized. In one or more embodiments, the thickness of the first dielectric layer 120 is 30 nm˜70 nm.

In one or more embodiments, the current spreading layer 112 is configured to further reduce the on-resistance and improve the reliability of the gate oxide. In addition, in one or more embodiments, the gate conductor 123 and the source conductor 121 share a trench, which saves the area of the device, reduces the size of the device, and reduces the cost.

In one or more embodiments, the L-shaped structure of the source conductor 121 increases the overlapping area of the source conductor 121 and the gate conductor 123 to further increase the source-gate capacitance, reduce the risk of parasitic conduction, and reduce the probability of failure caused by EMI.

In one or more embodiments, the channel diode is configured to reduce bipolar degradation effects due to the channel diode is unipolar device. By controlling the thickness of the first dielectric layer 120 and the doping concentration of the second body region 115 near the surface of the first dielectric layer 120.

Furthermore, the channel diode is a unipolar device (only electron), and there is no minority carrier recombination during reverse recovery so as to increase the reverse recovery capability.

In one or more embodiments, the depth of the first doped region is 116 greater than the depth of the trench 113. The second body region 115 surrounds the second sidewall 113b of the trench 113, at least a part of the bottom wall 113c of the trench 113, and a corner formed by the second sidewall 113b of the trench 113 and the bottom wall 113c of the trench 113. The first doped region 116 and the second body region 115 are to shield the electric field at the bottom of the trench 113 so as to protect the gate dielectric layer and improve the reliability of the gate dielectric layer.

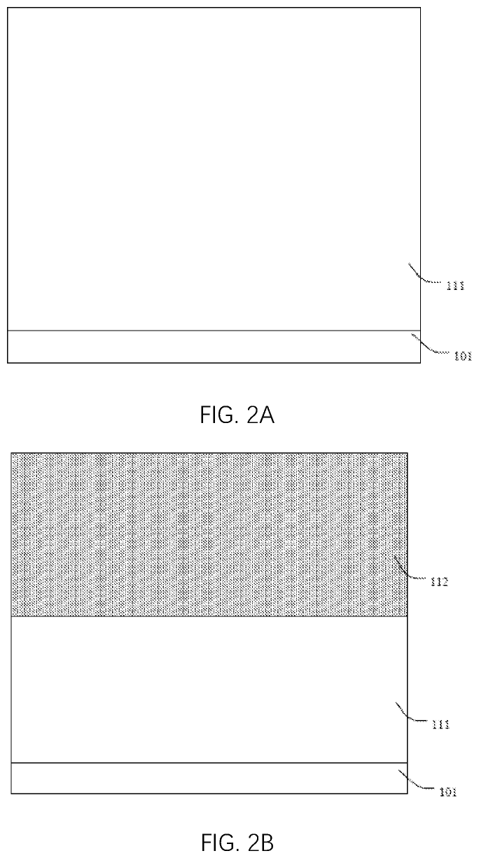

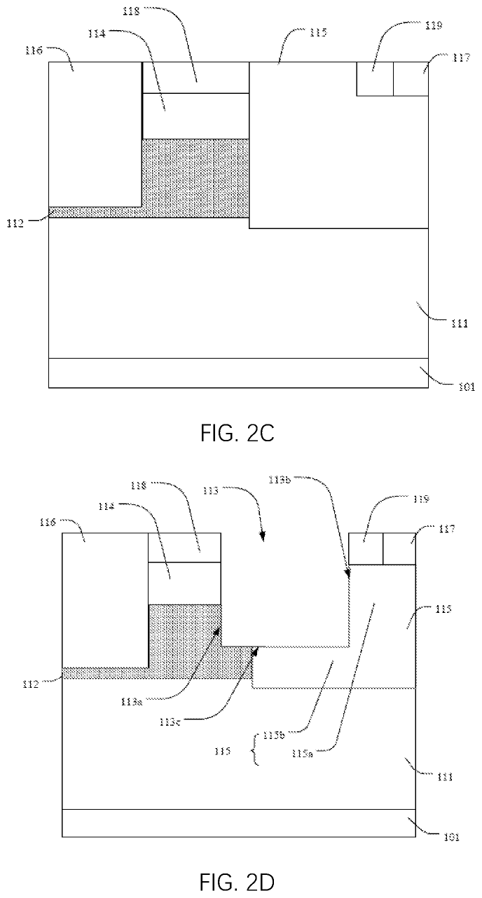

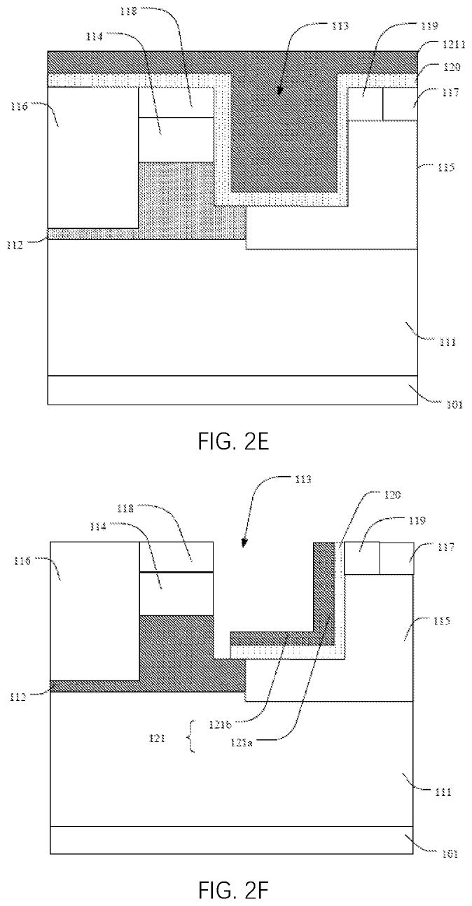

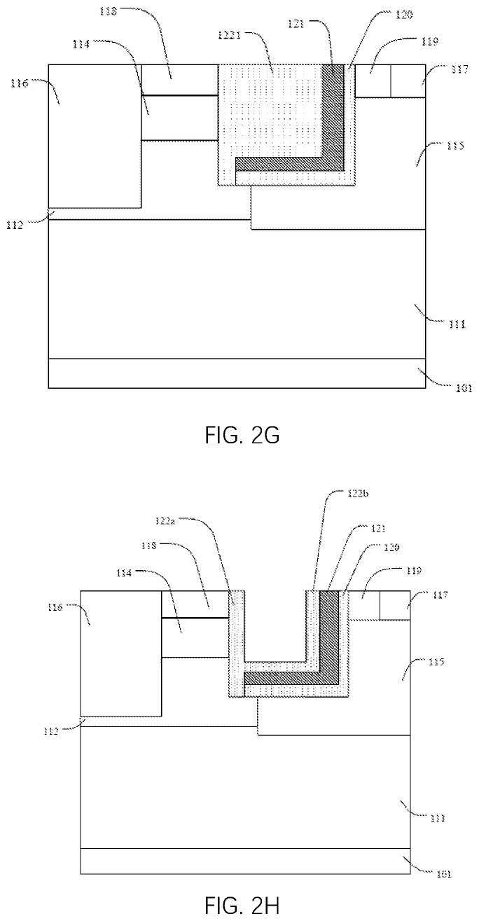

FIG. 2A to FIG. 2I show cross-sectional views of stages of a method for manufacturing an asymmetric trench MOSFET device according to one or more embodiments of the present disclosure.

As shown in FIG. 2A, an epitaxial layer 111 is formed on a substrate 101.

In this step, an epitaxial layer 111 is formed on the semiconductor substrate 101 using an epitaxial layer growth process. The substrate 101 and the epitaxial layer 111 are of a first doping type. The substrate 101 serves as a drain region of the device, and the epitaxial layer 111 serves as a drift region of the device. In one or more embodiments, the substrate 101 is heavily doped with N type, and the epitaxial layer 111 is lightly doped with N type, and the substrate 101 may be a silicon carbide (SiC) substrate.

As shown in FIG. 2B, a current spreading layer (CSL layer) 112 is formed in the epitaxial layer 111.

In this step, dopants of the first doping type are implanted into the epitaxial layer 111 by ion implantation, and a current spreading layer 112 of the first doping type is formed in the epitaxial layer 111. The current spreading layer 112 extends from the surface to the inside of the epitaxial layer 111. By controlling the parameters of ion implantation, such as implantation energy and dose, the desired depth and doping concentration can be achieved. In one or more embodiments, the current spreading layer 112 is heavily doped with N type. In other embodiments, the current spreading layer 112 may also be formed using epitaxial growth, which is not limited therein.

As shown in FIG. 2C, a first ion implantation is performed to form the first body region 114 and the second body region 115 of the second doping type.

In this step, for example, a deposition process is used to form a first mask on the surface of the current spreading layer (CSL layer) 112, a patterned first mask is formed by the photolithography and then the first ion implantation is performed by the patterned first mask. The first ion implantation implants dopants of the second doping type to form the first body region 114 and the second body region 115 respectively. By controlling the parameters of the first ion implantation, such as implantation energy and dose, the required depth and the required doping concentration can be achieved. In one or more embodiments, the first body region 114 and the second body region 115 are separated from each other. and have different depths. In other embodiments, the depth and doping concentration of the first body region 114 and the second body region 115 can be set as required. The first mask is removed after the first body region 114 and the second body region 115 are formed.

In one or more embodiments, the first body region 114 extends from the surface to the inside of the current spreading layer 112, and the bottom of the first body region 114 does not exceed the bottom of the current spreading layer 112, that is, the first body region 114 is located in the current spreading layer 112. The second body region 115 extends from the surface to the inside of the current spreading layer 112, and the bottom of the second body region 115 exceeds the bottom of the current spreading layer 112 and extends to the inside of the epitaxial layer 111, that is, the bottom of the second body region 115 is located in the epitaxial layer 111. In other embodiments, the implantation energy of the first ion implantation can also be controlled so that the bottom of the second body region 115 does not exceed the bottom of the current spreading layer 112, that is, the bottom of the second body region 115 is located in the current spreading layer 112.

Next, a second ion implantation is performed to form the first doped region 116 and the second doped region 117 of the second doping type.

In this step, for example, a deposition process is used to form a second mask on the surface of the epitaxial layer, a patterned second mask is formed by the photolithography and then a second ion implantation is performed through the patterned second mask. The second ion implantation implants dopants of the second doping type to form the first doping region 116 and the second doping region 117 respectively. By controlling the parameters of the second ion implantation, such as implantation energy and dose, the desired depth and doping concentration can be achieved.

In one or more embodiments, the first doped region 116 is adjacent to the first body region 114. The first doped region 116 extends from the surface to the inside of the current spreading layer 112, and the bottom of the first doped region 116 does not exceed the bottom of the current spreading region 112, that is, the first doped region 116 is located in the current spreading layer 112. In other embodiments, by controlling the implantation energy of the second ion implantation, the bottom of the first doped region 116 exceeds the bottom of the current spreading layer 112 and extends into the epitaxial layer 111, that is, the bottom of the first doped region 116 is located in the epitaxial layer 111.

The second doped region 117 is located in the second body region 115, the second doped region 117 extends from the surface to the inside of the second body region 115, and the bottom of the second doped region 117 does not exceed the bottom of the second body region 115.

Next, a third ion implantation is performed to form a third doped region 118 and a fourth doped region 119 of the first doping type.

In this step, for example, a deposition process is used to form a third mask on the surface of the epitaxial layer, a patterned third mask is formed by photolithography, and then the third ion implantation is performed on the epitaxial layer through the patterned third mask. The third ion implantation implants dopants of the first doping type into the epitaxial layer 111 to form the third doping region 118 and the fourth doping region 119 in the epitaxial layer 111. By controlling the parameters of the third ion implantation, such as implantation energy and dose, the desired depth and doping concentration can be achieved.

In one or more embodiments, the third doped region 118 is located in the first body region 114 and adjacent to the first doped region 116. The third doped region 118 extends from the surface to the inside of the epitaxial layer 111, and the depth of the third doped region 118 extending in the epitaxial layer is smaller than the depth extending in the epitaxial layer 111 of the first body region 114. The fourth doped region 119 is located in the second body region 115 and is adjacent to the second doped region 117 in the second body region 115.

As shown in FIG. 2D, the trench 113 is formed.

For example, a deposition process is used to form a mask, a patterned mask is formed by the photolithography, and then the epitaxial layer 111 not covered by the mask is etched to form the trench 113 in the epitaxial layer 111. The trench 113 includes the first sidewalls 113a (i.e., the left sidewall in FIG. 1), the second sidewalls 113b (i.e., the right sidewall in FIG. 1), and the bottom wall 113c connecting the first sidewall 113a and the second sidewall 113b. The first sidewalls 113a, the second sidewalls 113b and the bottom wall 113c of the trench 113 constitute the inner surface of the trench 113. In one or more embodiments, dry etch can be used for etching, such as ion milling etching, plasma etching, reactive ion etching, and laser ablation. In one or more embodiments, the mask may be a photoresist mask, and the mask is removed after the trench 113 is formed.

The first body region 114, the first doped region 116 and the third doped region 118 are located on the first side of the trench 113 (i.e., the left side in FIG. 2D). The second body region 115, the second doped region 117 and the fourth doped region 119 are located on the second side of the trench 113 (i.e., the right side in FIG. 2D). The first body region 114 and the third doped region 118 are adjacent to the first sidewall 113a of the trench 113 and, the fourth doped region 119 is adjacent to the second sidewall 113b of the trench 113.

The extension depth of the first doped region 116 in the epitaxial layer 111 is greater than the extension depth of the trench 113 in the epitaxial layer 111. The extension depth of the second body region 115 in the epitaxial layer 111 is greater than the trench 113 in the epitaxial layer 111. After the trench 113 is formed, a part of the second body region 115 is removed, and the remaining second body region 115 surrounds the second sidewalls 113b of the trench 113 and a part of the bottom wall 113c of the trench 113. The trench 113 is half surrounded by the second body region 115.

After the trench 113 is formed, the remaining second body region 115 includes a third portion 115a located on the second sidewall 113b of the trench 113, and a fourth portion 115b located below the trench 113, the third portion 115a and the fourth portion 115b are connected to form an integration surrounding the second sidewall 113b of the trench 113, at least a part of the bottom wall 113c of the trench 113, and a corner formed by the second sidewall 113b of the trench 113 and the bottom wall 113c of the trench 113. Wherein, one end of the fourth part 115b is connected to the third part 115a, and the other end extends away from the third part 115a.

As shown in FIG. 2E, a first dielectric layer 120 and a conductive layer 1211 are formed.

In this step, for example, the first dielectric layer 120 is formed on the inner surface of the trench 113 (the bottom wall 113c, the first sidewalls 113a and the second sidewalls 113b of the trench 113) and the upper surface of the epitaxial layer 111 by a deposition method, that is, the first dielectric layer 120 covers the inner surface of the trench 113 and the surface of the current spreading layer 112. The first dielectric layer 120 is, for example, a silicon oxide layer.

A conductive layer 1211 is formed on the first dielectric layer 120 by low pressure chemical vapor deposition, and the conductive layer 1211 includes a portion in the trench 113 and a portion above the current spreading layer 112. The conductive layer 1211 is, for example, a polysilicon layer.

As shown in FIG. 2F, the portion of the conductive layer 1211 above the epitaxial layer 111 is removed by etch back or chemical mechanical planarization, so that the upper end of the conductive layer 1211 terminates at the opening of the trench. In one or more embodiments, the first dielectric layer 120 above the epitaxial layer 111 is removed at the same time.

The portion of the conductor layer 1211 located in the trench is etched to obtain an L-shaped source conductor 121. The part of the first dielectric layer 120 inside the trench is etched to leave only between the source conductor 121 and the second sidewalls 113b of the trench 113 and between the source conductor 121 and a part of the bottom wall 113c of the trench 113.

The source conductor 121 includes a first portion 121a and a second portion 121b which are perpendicular to each other. One end of the first portion 121a is connected to one end of the second portion 121b to form an L-shaped source conductor 121. The source conductor 121 is isolated from the inner surface of the trench 113 by the first dielectric layer 120, specifically, the first portion 121a of the source conductor 121 is isolated from the second sidewalls 113b of the trench 113 by the first dielectric layer 120, the second portion 121b is isolated from the bottom wall 113c of the trench 113 by the first dielectric layer 120.

The second portion 121b of the source conductor 121 and the fourth portion 115b of the second body region 115 extend in the first direction (for example the negative direction of the X axis in FIG. 1), and in the first direction, the end of the fourth portion 115b away from the third portion 115a does not exceed the end of the second portion 121b away from the first portion 121a.

As shown in FIG. 2G a second dielectric layer 1221 is formed.

In this step, the second dielectric layer 1221 is formed in the trench 113 and on the upper surface of the epitaxial layer 111 by a deposition method. The portion of the conductive layer 1211 above the epitaxial layer 111 is removed by etch back or chemical mechanical planarization, so that the upper end of the conductive layer 1211 terminates at the opening of the trench. The upper surface of the second dielectric layer 1221 is flush with the upper surface of the epitaxial layer 111.

As shown in FIG. 2H, a gate trench is formed in the second dielectric layer 1221.

In this step, for example, a deposition process is used to form a mask on the upper surface of the second dielectric layer 1221 and the upper surface of the epitaxial layer 111, a patterned mask is formed by photolithography, and then the second dielectric layer 1221 not covered by the mask in the trench 113 is etched to form a gate trench in the second dielectric layer 1221. In one or more embodiments, dry etch can be used for etching, such as ion milling etching, plasma etching, reactive ion etching, and laser ablation. In one or more embodiments, the mask may be a photoresist mask, and the mask is removed after forming the gate trench.

The first sidewall of the gate trench is flush with the end of the second portion 121b of the source conductor 121 away from the first portion 121a. After the gate trench is formed, the second dielectric layer 1221 between the first sidewall of the gate trench and the inner surface of the trench 113 (specifically, the first sidewalls 113a of the trench) is remained to form the gate dielectric layer 122a. The second dielectric layer between the bottom of the gate trench and the second portion 121b of the source conductor 121 and the second dielectric layer between the second sidewall of the gate trench and the first portion 121a of the source conductor 121 are remained to form the isolation dielectric layer 122b.

As shown in FIG. 2I, a gate conductor 123 is formed.

In this step, a conductor layer is formed in the gate trench and on the upper surface of the epitaxial layer 111 by low pressure chemical vapor deposition.

The portion of the conductor layer above the epitaxial layer 111 is removes by etch back or chemical mechanical planarization, so that the upper end of the conductor layer terminates at the opening of the trench. The upper surface of the conductor layer is flush with the upper surface of the epitaxial layer 111 to form the gate conductor 123.

The first side of the gate conductor 123 is isolated from the inner surface of the trench 113 (specifically, the first sidewalls 113a of the trench) by the gate dielectric layer 122a. The bottom and the second side of the gate conductor 123 are isolated from the source conductor 121 by the isolation dielectric layer 122b.

Next, an interlayer dielectric layer 124 is formed.

The interlayer dielectric layer 124 is formed on the surface of the first doped region 116, the surface of the second doped region 117, the surface of the third doped region 118, the surface of the fourth doped region 119, the surface of the gate conductor 123 and a part of the surface of the source conductor 121 by the deposition process, and then a chemical mechanical planarization process is performed to obtain a flat surface.

A conductive channel 125 penetrating through the interlayer dielectric layer 124 to reach the source conductor 121 is formed by an etching process, and a source electrode 126 is formed on the conductive channel 125, and the source electrode 126 is connected to the source conductor 121 via the conductive channel 125. The drain electrode 127 is formed on the second surface of the substrate 101 by the deposition process to obtain the asymmetric trench MOSFET 100 as shown in FIG. 1.

In one or more embodiments, the source conductor, the source electrode, the gate conductor, and the drain electrode 124 can be formed of conductive materials. In one or more embodiments, the conductive material may be metal materials such as aluminum alloy or copper.

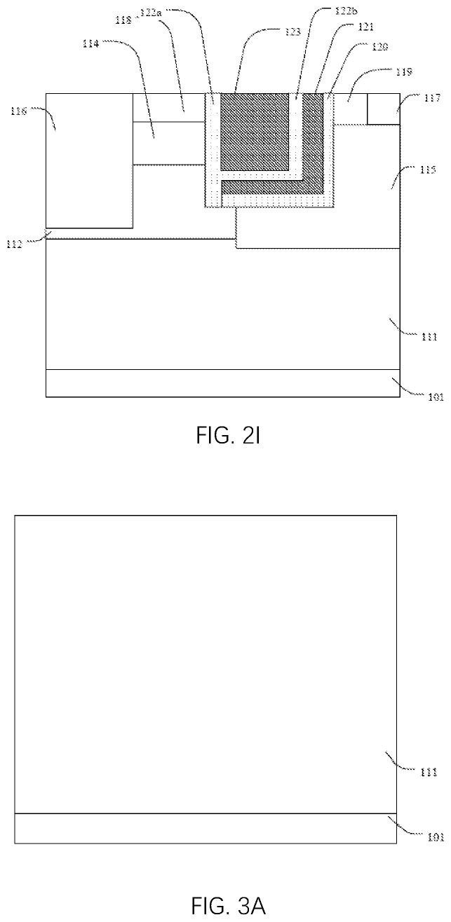

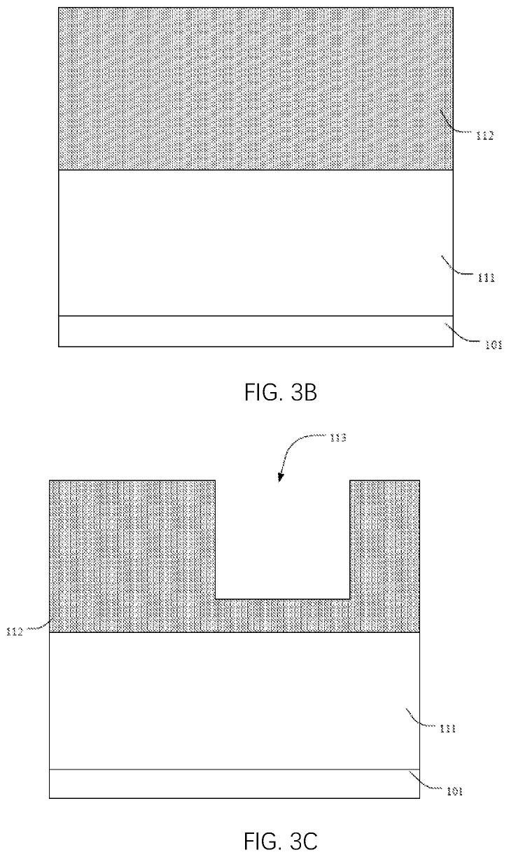

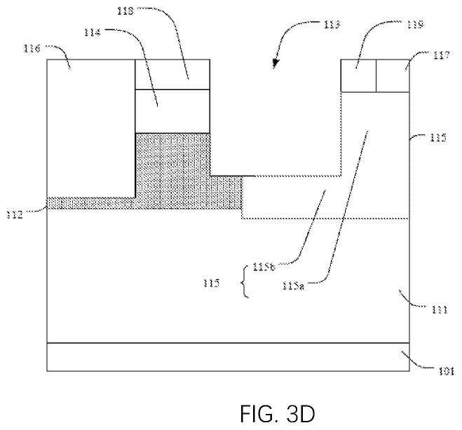

FIG. 3A to FIG. 3D show cross-sectional views of steps of a method for manufacturing an asymmetric trench MOSFET device according to one or more embodiments of the present disclosure.

The steps shown in FIG. 3A and FIG. 3B are the same as shown in FIG. 2A and FIG. 2B, which will not be repeated therein.

As shown in FIG. 3C, the trench 113 is formed.

For example, a deposition process is used to form a mask, a patterned mask is formed by the photolithography and then the epitaxial layer 111 not covered by the mask is etched to form a trench 113 in the epitaxial layer 111. In one or more embodiments, dry etch can be used for etching, such as ion milling etching, plasma etching, reactive ion etching, and laser ablation. In one or more embodiments, the mask may be a photoresist mask, and the mask is removed after the trench 113 is formed.

As shown in FIG. 3D, the first ion implantation is performed to form the first body region 114 and the second body region 115 of the second doping type. The second ion implantation is performed to form the first doped region 116 and the second doped region 117 of the second doping type. The third ion implantation is performed to form the third doped region 118 and the fourth doped region 119 of the first doping type.

The second body region 115 includes a third portion 115a located on the second sidewall of the trench 113 and a fourth portion 115b located below the trench 113. The third portion 115a and the fourth portion 115b are connected to form an integration. The second body region 115 surrounds the second sidewall of the trench 113, at least a part of the bottom wall of the trench 113, and a corner formed by the second sidewall of the trench 113 and the bottom wall of the trench 113.

The method for forming the first dielectric layer, source conductor, isolation dielectric layer, gate dielectric layer, gate conductor, interlayer dielectric layer, conductive channel, source electrode and drain electrode herein is the same as above one or more embodiments in the present disclosure, which will not be repeated therein.

In one or more embodiments, the trench 133 is formed first, and then the first body region 114, the second body region 115, the first doped region 116, the second doped region 117, the third doped region 118 and the fourth doped region 119 are formed, such that the positions of the first body region 114, the second body region 115, the first doped region 116, the second doped region 117, the third doped region 118, and the fourth doped region 119 are determined according to the position of the trench 113.

The embodiments in accordance with the present disclosure, as described above, neither describe all details thoroughly nor limit the present disclosure, and are only the specific embodiments. Apparently, many modifications and variations are possible in light of the above description. These embodiments are selected and specifically described in this description to better explain the principle and practical application of the present disclosure, so that those skilled in the art may make good use of the present disclosure and modifications based on the present disclosure. The present disclosure is to be limited only by the claims and their full scope and equivalents.

What is claimed is:

1. A gate-source structure of an asymmetric trench metal oxide semiconductor field effect transistor (MOSFET), comprising:
a substrate of a first doping type;
an epitaxial layer of the first doping type on the substrate;
a current spreading layer of the first doping type in the epitaxial layer;
a trench extending from a surface to an inside of the current spreading layer;
a source conductor located in the trench;
a first dielectric layer, located between the source conductor and an inner surface of the trench, configured to isolate from the source conductor and the inner surface of the trench;
a gate conductor located in the trench;
an isolation dielectric layer, located between the source conductor and the gate conductor, configured to isolate from the source conductor and the gate conductor;
a gate dielectric layer, located between the gate conductor and the inner surface of the trench, configured to isolate from the gate conductor and the inner surface of the trench;
wherein:
the source conductor includes:
a first portion opposite to a side of the gate conductor; and
a second portion opposite to a bottom of the gate conductor; and
the first portion and the second portion are perpendicular and connected to each other.

2. An asymmetric trench metal oxide semiconductor field effect transistor (MOSFET), comprising:
a substrate of a first doping type;
an epitaxial layer of the first doping type on the substrate;
a current spreading layer of the first doping type in the epitaxial layer;
a trench extending from a surface to an inside of the current spreading layer;
a source conductor located in the trench;
a first dielectric layer, located between the source conductor and an inner surface of the trench, configured to isolate from the source conductor and the inner surface of the trench;
a gate conductor located in the trench;
an isolation dielectric layer, located between the source conductor and the gate conductor, configured to isolate from the source conductor and the gate conductor;
a gate dielectric layer, located between the gate conductor and the inner surface of the trench, configured to isolate from the gate conductor and the inner surface of the trench;
a first body region located adjacent a first sidewall of the trench;
a second body region located adjacent a second sidewall of the trench, the first sidewall of the trench opposite to the second sidewall of the trench;
wherein:
the source conductor includes:
a first portion opposite to a side of the gate conductor; and
a second portion opposite to a bottom of the gate conductor; and
the first portion and the second portion are perpendicular and connected to each other.

3. The asymmetric trench MOSFET according to claim 2, wherein the second body region comprises:
a third portion located adjacent the second sidewall of the trench; and
a fourth portion located below the trench;
wherein the third portion and the fourth portion are connected together to form an integration, surrounding the second sidewall of the trench, at least a part of a bottom wall of the trench, and a corner formed by the second sidewall of the trench and the bottom wall of the trench.

4. The asymmetric trench MOSFET according to claim 3, wherein both the second portion and the fourth portion extend in a first direction, and in the first direction, an end of the fourth portion away from the third portion is not excess an end of the second portion away from the first portion.

5. The asymmetric trench MOSFET according to claim 2, further comprises:
a first doped region of a second doping type, the first doped region located adjacent a side of the first body region away from the trench;
a third doped region of the first doping type located in the first body region and adjacent to the trench;
a fourth doped region of the first doping type located in the second body region and adjacent to the trench; and
a second doped region of a second doping type, located in the second body region, and adjacent to a side of the fourth doped region away from the trench.

6. The asymmetric trench MOSFET according to claim 5, wherein the first doped region extends from a surface to the inside of the current spreading layer, and a depth of the first doped region in the current spreading layer is greater than a depth of the trench in the current spreading layer.

7. The asymmetric trench MOSFET according to claim 5, wherein a bottom of the first doped region is located in the current spreading layer or in the epitaxial layer.

8. The asymmetric trench MOSFET according to claim 2, wherein a bottom of the second body region is located in the current spreading layer or in the epitaxial layer.

9. A method for manufacturing a gate-source structure of an asymmetric trench metal oxide semiconductor field effect transistor (MOSFET), comprising:
sequentially forming an epitaxial layer and a current spreading layer on a substrate, the substrate, the epitaxial layer, and the current spreading layer being of a first doping type;
forming a trench extending from a surface to an inside of the current spreading layer;
forming a source conductor in the trench, and a first dielectric layer between the source conductor and an inner surface of the trench, the first dielectric layer isolating from the source conductor and an inner surface of the trench; and
forming a gate conductor, an isolation dielectric layer between the source conductor and the gate conductor and a gate dielectric layer between the gate conductor and the inner surface of the trench in the trench, the isolation dielectric layer isolating from the source conductor and the gate conductor and the gate dielectric layer isolating from the gate conductor and the inner surface of the trench.

10. The method of claim 9, wherein the method of forming a source conductor and a first dielectric layer between the source conductor and the current spreading layer in the trench comprises:
forming a first dielectric layer, covering the inner surface of the trench and the surface of the current spreading layer;
forming a conductor layer on the first dielectric layer, the conductor layer including a portion in the trench and a portion on the current spreading layer;
removing the portion of the first dielectric layer on the current spreading layer and the portion of the conductor layer on the current spreading layer;
etching a part of the conductor layer located in the trench to obtain the source conductor; and
etching a part of the first dielectric layer located in the trench, leaving only the first dielectric layer between the source conductor and the current spreading layer;
wherein:
the source conductor comprises:
a first portion opposite to a side of the gate conductor; and
a second portion opposite a bottom of the gate conductor; and
the first part and the second part are perpendicular and connected to each other.

11. The method of claim 9, wherein the method of forming a gate conductor, an isolation dielectric layer between the source conductor and the gate conductor, and a gate dielectric layer between the gate conductor and the inner surface of the trench in the trench includes:
forming a second dielectric layer in the trench, the second dielectric layer including a portion located in the trench and a portion located on the current spreading layer;
removing the portion of the second dielectric layer on the current spreading layer; and
etching the portion of the second dielectric layer located in the trench to form a gate trench;
forming a gate conductor in the gate trench;
wherein:
after forming the gate trench, the second dielectric layer located between a first sidewall of the gate trench and the inner surface of the trench is retained to form a gate dielectric layer;
the second dielectric layer located between a bottom of the trench and the source conductor, and the second dielectric layer located between a second sidewall of the gate trench and the source conductor are retained to form an isolation dielectric layer; and
the first sidewall of the gate trench is opposite to the second sidewall of the gate trench.

12. A method of manufacturing an asymmetric trench metal oxide semiconductor field effect transistor (MOSFET), comprising:
sequentially forming an epitaxial layer and a current spreading layer on a substrate, the substrate, the epitaxial layer, and the current spreading layer being of a first doping type;
forming a trench extending from a surface to an inside of the current spreading layer;
forming a source conductor in the trench, and a first dielectric layer between the source conductor and an inner surface of the trench, the first dielectric layer isolating from the source conductor and an inner surface of the trench;
forming a gate conductor, an isolation dielectric layer between the source conductor and the gate conductor and a gate dielectric layer between the gate conductor and the inner surface of the trench in the trench; the isolation dielectric layer isolating from the source conductor and the gate conductor and the gate dielectric layer isolating from the gate conductor and the inner surface of the trench; and
forming a first body region and a second body region of a second doping type;
wherein:
the first body region located adjacent to a first sidewall of the trench; and
the second body region located adjacent to a second sidewall of the trench, the first sidewall of the trench being opposite to the second sidewall of the trench.

13. The method of claim 12, wherein the method of forming a source conductor and a first dielectric layer between the source conductor and the current spreading layer in the trench comprises:
forming a first dielectric layer, covering an inner surface of the trench and a surface of the current spreading layer;
forming a conductor layer on the first dielectric layer, the conductor layer including a portion in the trench and a portion on the current spreading layer;
removing the portion of the first dielectric layer on the current spreading layer and the portion of the conductor layer on the current spreading layer;
etching a part of the conductor layer located in the trench to obtain the source conductor;
etching a part of the first dielectric layer located in the trench, leaving only the first dielectric layer between the source conductor and the current spreading layer;
wherein, the source conductor comprises:
a first portion opposite to a side of the gate conductor; and
a second portion opposite a bottom of the gate conductor; and
the first part and the second part are perpendicular and connected to each other.

14. The method of claim 12, wherein the method of forming a gate conductor, an isolation dielectric layer between the source conductor and the gate conductor, and a gate dielectric layer between the gate conductor and the inner surface of the trench in the trench comprises:
forming a second dielectric layer in the trench, the second dielectric layer including a portion located in the trench and a portion located on the current spreading layer;
removing the portion of the second dielectric layer on the current spreading layer;
etching the portion of the second dielectric layer located in the trench to form a gate trench;
forming a gate conductor in the gate trench;
wherein:
after forming the gate trench, the second dielectric layer located between a first sidewall of the gate trench and the inner surface of the trench is retained to form a gate dielectric layer;
the second dielectric layer located between a bottom of the trench and the source conductor and the second dielectric layer located between a second sidewall of the gate trench and the source conductor are retained to form an isolation dielectric layer; and
the first sidewall of the trench is opposite to the second sidewall of the gate trench.

15. The method of claim 12, wherein the method of forming the second body region comprises: forming the second body region of a second doping type before forming the trench;
after forming the trench, at least a part of the second body region being removed to form a remaining second body region that comprises:
a third portion on the second sidewall of the trench, the third portion located adjacent to the trench; and
a fourth portion located below the trench;
wherein the third portion and the fourth portion are connected together to form the second body region, the second body region surrounding the second sidewall of the trench, a part of a bottom wall of the trench and a corner formed by the second sidewall of the trench and the bottom wall of the trench.

16. The method of claim 12, wherein the method of forming the second body region comprises: forming the second body region of the second doping type after forming the trench;
forming the second body region including:
forming a third portion located adjacent to the second sidewall of the trench; and
forming a fourth portion located below the trench;
wherein the third portion and the fourth portion are connected together to form the second body region, the second body region surrounding the second sidewall of the trench, at least a part of a bottom wall of the trench and a corner formed by the second sidewall of the trench and the bottom wall of the trench.

17. A method according to claim 15, wherein both the second portion and the fourth portion extend in a first direction, and in the first direction, an end of the fourth portion away from the third portion is not excess an end of the second portion away from the first portion.

18. The method of claim 12, wherein a bottom of the second body region is located in the current spreading layer or in the epitaxial layer.

19. The method of claim 12, wherein further comprises:
forming a first doped region and a second doped region of the second doping type; and
forming a third doped region and a fourth doped region of the first doping type;
wherein:
the first doped region is located adjacent to a side of the first body region away from the trench;
the third doped region is located in the first body region and is adjacent to the trench;
the fourth doped region is located in the second body region and is adjacent to the trench; and
the second doped region is located in the second body region, and the second doped region is located adjacent to a side of the fourth doped region away from the trench.

20. The method of claim 19, wherein the first doped region extends from a surface to the inside of the current spreading layer, and a depth of the first doped region in the current spreading layer is greater than a depth of the trench in the current spreading layer.
